(19) United States
(12) Patent Application Publication
(10) Pub. No.: US 2011/0273171 A1
(43) Pub. Date: Nov. 10, 2011

(54) METHOD AND DEVICE FOR DETERMINING WHETHER THERE IS A CHANGE IN A SUBSTRATE BENEATH A LAYER COVERING THE SUBSTRATE

(76) Inventors: Ing. Gerrit Gehnen, Schwalmtal (DE); Volker K.S. Feige, Dusseldorf (DE)

(21) Appl. No.: 12/774,485

(22) Filed: May 5, 2010

(51) Int. Cl. G01R 33/02; G01R 27/08

(52) U.S. Cl. 324/244; 324/705

(57) ABSTRACT

The invention relates to a method for determining whether there is a change in a substrate (2) beneath a layer (1) covering the substrate (2). To this end, a combined magnetic and/or electrical measurement is taken at one location on the substrate (2) on or at a distance from the covering layer (1) using at least two different measuring methods. An examination is then conducted as to whether a relationship between measurement values which are ascertained using different measuring methods matches a reference relationship, wherein if there is a deviation, it is established that the substrate (2) has been changed.

The present invention relates to a method for determining whether there is a change in a substrate beneath a layer covering the substrate, and to a measuring device for measuring a layer thickness of a covering layer on a substrate.

A substrate can for example be the body of a vehicle which is covered by a layer of paint. Locating a welding seam or welding spot beneath the coat of paint can be important in many situations, for example when buying a used vehicle. The potential buyer is then faced with the question: does the vehicle match the seller's claims? Has it really never had an accident, or has it already suffered damage due to an accident, which has been repaired by affixing new sheet metal parts by means of welding, wherein the welding seams are hidden beneath a coat of paint?

DE 1 473 696 B discloses a device for non-destructive material testing, consisting of: an induction means for generating a magnetic field which changes over time in pulses or periodically and induces eddy currents in the test object which generate a magnetic field which correlates with the properties of or defects in the test object; and magnetically sensitive testing agents for the magnetic field generated by the eddy currents. The testing agents consist of at least one magnetically sensitive semiconductor.

DE 1 773 857 C discloses a device for non-destructively material-testing metallic materials on the basis of eddy currents, which comprises: a probe which senses a magnetic field and comprises a magnetising coil and a Hall effect means, which are magnetically coupled to each other; a first oscillator comprising an output signal at a frequency f₁ which is supplied to the magnetising coil, thus generating a magnetic field; and an indicating device, which is connected to a demodulator, for indicating the amplitude of the demodulated signal. The Hall effect means is provided with a second oscillator comprising an output signal at a frequency f₂. A mixing means is applied to the first and second oscillators in order to superimpose the first and second oscillator output signals at the frequency f₁, f₂. A device which is connected to the mixing means and the Hall effect means feeds the superimposed signals into the Hall effect means. The demodulator, which is connected to the output of the Hall effect means, is adjusted to the frequency f₂.

DE 4 333 419 A1 discloses a method and device for measuring the layer thickness of non-ferrous or non-magnetic layers on a ferrous or magnetic substrate and non-conductive layers on a conductive substrate. The method comprises the following steps: testing whether a substrate is a ferrous substrate by measuring a magnetic flux density at a pole of a magnet which is situated in the measuring probe; determining the layer thickness on the basis of the measured magnetic flux density, if a ferrous substrate is ascertained; or measuring eddy current effects which occur in the substrate and determining the layer thickness on the basis of this measurement, if the substrate is a conductive substrate.

It is an object of the invention to improve the known methods for material-testing a substrate beneath a covering layer, with regard to reliability.

The above object is solved by the subjects of the independent claims. The dependent claims are directed to advantageous developments.

One aspect of the invention relates to a method for determining whether there is a change in a substrate beneath a layer covering the substrate. The substrate can be a ferromagnetic and electrically conductive material; the covering layer can be a poorly conductive material. The method can in particular be used to non-destructively test electrically conductive and magnetisable substrates.

At one location on the substrate, a combined magnetic and/or electrical measurement can be taken on or at a distance from the covering layer using at least two different measuring methods. This can mean that at least two individual measurements are taken, wherein one individual measurement is taken using one measuring method, a second individual measurement is taken using another measuring method, etc. A combined measurement can be understood to mean taking a number of measurements using different methods. Advantageously, measuring at a distance is expedient when contact between a measuring head of a measuring device and the covering layer is to be avoided, for example when the covering layer is a pressure-sensitive layer of paint or when the substrate is not covered, such that for example the air in the measuring gap between the measuring head and the substrate is the covering layer.

A change in a substrate is identified in accordance with whether a relationship and/or reference relationship, which is established in a reference region, between measurement values which are ascertained using different measuring methods remains unchanged in a test region. “Reference region” can be understood to mean a geometric region of the substrate in which the substrate has very probably not been changed, for example by deliberate manipulations, and is thus in its original state. The reference relationship is obtained from the measurement results procured in the reference region. The reference relationship is stored and compared with the relationship obtained from measurement results in the test region. “Test region” is understood to mean a region of the substrate in which measurements are to be used to establish whether the substrate is unchanged relative to the reference region. If the relationship between the measurement values obtained in the test region using different methods deviates from the reference relationship, then the substrate has been changed in the test region. The material properties of the substrate advantageously do not have to be quantitatively known, since only relationships or functional dependencies between measurement values are tested.

In accordance with one embodiment, the measurement values can be assigned to a layer thickness of the covering layer.

A detection criterion for a change in the substrate in the test region relative to the original state which obtains in the reference region can be defined such that the detection criterion is fulfilled if the relationship in the test region deviates from the reference relationship.

The reference relationship can preferably be that the measurement values ascertained at a measurement location using one measuring method are in a constant relationship with respect to the measurement values ascertained at the same measurement location using another measuring method.

The reference relationship can preferably be a constant 1:1 relationship. The detection criterion is then tested by polling whether the values obtained using the at least two different measuring methods are identical. If the values are not identical, it is established that the substrate has been changed.

In a 2D co-ordinate system, in which the measurement values ascertained using a first and a second measuring method are plotted on one axis each, the measured values can lie on a detection curve, if they do not fulfil the detection criterion. If the relationship is that the measurement values ascertained using one measuring method, respectively, are in a constant relationship with respect to each other, then the detection curve is a straight line. Fulfilling the detection criterion would result in the measurement values deviating from the straight line, i.e. lying off the straight line, in the 2D chart. This enables an operator to visually verify on a screen whether the detection criterion is fulfilled. The detection criterion can be automatically triggered by computationally testing whether the measurement values are situated within a corridor around the detection curve or around the straight line, wherein the width of the corridor can be preset.

There is a change in a substrate when the measured locations on the substrate have material properties, such as for example electrical conductivity and/or magnetic permeability, which deviate from the material properties of the substrate in the reference region. A deviation exists for example at a join between materials exhibiting different magnetic permeability values, at a welding seam, or at a structural change in the substrate, for example a notch or cavity.

A piece can be cut out of the original material at a particular location on a substrate and replaced with another. The new material can have a magnetic permeability which differs from that of the original material in the reference region. When taking measurements across the join, the different measuring methods can produce measurement values which fulfil the detection criterion.

At another location on the substrate, a piece of the substrate which has been cut out can be replaced with one which exhibits identical material properties, wherein a welding seam exists. When taking measurements across the welding seam, the structural change at the join can result in measurement values which fulfil the detection criterion.

In accordance with one embodiment, the at least two different measuring methods can be a static and a dynamic measuring method. If the measurement values are to be assigned to a thickness, then it is advantageously possible—if the layer thickness and the substrate properties are locally changed simultaneously—to largely avoid compensating for the measurable effects of these changes, i.e. when using a single measuring method, it is possible for a local change in the layer thickness and the substrate properties simultaneously to compensate for each other, such that the measurement indicates a constant layer thickness. By contrast, when using a static and a dynamic measuring method in combination, the likelihood of measurement influences which cancel each other out is much lower using the two measuring methods, and the reliability of the conclusion obtained from the measurement is therefore much greater.

For the static method, a static magnetic field can for example be generated with the aid of a permanent magnet or a coil through which a constant current flows, and for the dynamic method, a dynamic magnetic field can for example be generated with the aid of a coil through which an alternating current flows. Advantageously, it is therefore possible to measure the layer thickness of an electrically non-conductive and substantially non-magnetising layer on a ferromagnetic, highly electrically conductive substrate.

In accordance with one embodiment, a calibration can be respectively performed for each measuring method, before the combined measurement is taken. A functional dependency of a measurement value, for example a voltage or a current, on the layer thickness of the covering layer can be established while measuring. The measured voltage is thus a function of the layer thickness. This function is characteristic of a measuring method and a measured object. A “calibration” is for example understood to mean ascertaining the inverse function, also referred to as the calibrating function, within the context of reference measurements, individually for the measuring method used and for the measured object, wherein the layer thickness is a function of the measured voltage. Since the values of the actual layer thickness and the measured layer thickness can deviate from each other, a match between measured values and actual values can be established while calibrating by adapting the calibrating function. A “reference measurement” is for example understood to mean a combined measurement which is taken in the reference region of the substrate.

Calibrating can also serve to define the reference relationship between measurement values ascertained using different measuring methods, and to ascertain the detection curve in the reference region. The detection curve is composed of measurement values which are obtained using different measuring methods in the reference region and which match the reference relationship.

Advantageously, a reference measurement—as also a measurement in the test region—can be taken at a defined distance, for example by means of positioning the measuring head of the measuring device at a defined distance from the covering layer, or from the substrate if there is no covering layer. The measuring head can for example be moved over the reference region or the test region automatically in accordance with a pattern which can be preset, wherein the measurements are taken at regular time intervals. The measuring head can for example be positioned at a defined distance and moved at a defined height by means of an external device and/or a mechanical device which is integrated in the measuring head.

Advantageously, a combined and/or synchronous calibration can be performed for each measured object. A “combined calibration” is understood to mean performing calibrations for all the available measuring methods. A “synchronous calibration” is understood to mean performing simultaneous or near-simultaneous combined calibrations.

In accordance with another embodiment, a zero adjustment can be respectively made for each measuring method, before the combined measurement is taken. A “zero adjustment” is understood to mean adapting the calibrating function, within the context of reference measurements, by means of a mathematical operation, for example adding or subtracting an offset amount in order to compensate for offset effects. In a 2D co-ordinate system, in which the measurement values ascertained using a measuring method are plotted on one axis each, the zero adjustment causes the detection curve to pass through the intersection point of the co-ordinate axes.

Advantageously, a combined and/or synchronous zero adjustment can be made for each measured object. A “combined zero adjustment” is understood to mean making zero adjustments for all the available measuring methods. A “synchronous zero adjustment” is understood to mean making simultaneous or near-simultaneous combined zero adjustments.

In accordance with one embodiment, the calibration and/or the zero adjustment can comprise at least one reference measurement, i.e. a combined measurement in the reference region, wherein the following steps can be performed: placing a stack of one or more reference layers, which have a thickness which is known beforehand, onto the covering layer or onto the substrate which is not covered or coated; and taking a combined measurement on the substrate with the stack placed on it. The reference layers can have uniform or different thicknesses, such that any thicknesses can be achieved by means of stacking a number of reference layers.

The calibrating function can be mathematically approximated by a polynomial which is dependent on the layer thickness. Adapting the calibrating function can mean that the polynomial coefficients of the approximated calibrating function are determined in such a way that one or more ancillary conditions are fulfilled. An ancillary condition can be that the detection curve in a 2D co-ordinate system, in which the measurement values ascertained using the first and the second measuring method are plotted on one axis each, exhibits a profile which can be preset, for example a straight line. This process is referred to as linearisation. Defining the detection curve also implicitly defines the reference relationship.

In accordance with another embodiment, the method can comprise a combined measurement featuring at least two partial steps. In one partial step, a measurement is taken using only one of the at least two measuring methods, wherein the partial steps are performed simultaneously or near-simultaneously or sequentially. The advantage of simultaneous or near-simultaneous measurements is that if the measurements are taken in the course of a movement by the measuring head over the substrate, the partial measurements of a combined measurement are taken at the same measurement location and thus provide information about the same layer thickness of the covering layer.

In accordance with one embodiment, a series of measurements comprising a multitude of combined measurements can be taken at different measurement locations on the substrate. Each individual measurement in the series of measurements can be taken at one measurement location, and the series of measurements can be taken within a locational range consisting of a multitude of measurement locations. The measurements taken using one measuring method produce one layer thickness matrix; the measurements taken using another measuring method produce a second layer thickness matrix, etc. Each layer thickness matrix shows a functional locational dependency between the layer thicknesses measured using the measuring method in question. By comparing the measured layer thickness matrices, it is possible to obtain a statement about the location or locational range at which the detection criterion is fulfilled. If, for example, the locational range comprises a welding spot or a welding seam along a line, the point or line can be located by taking the series of measurements.

In accordance with one embodiment, the series of measurements can be taken by means of a measuring device. The series of measurements can be taken during a movement of the measuring device on or at a distance from the covering layer.

A “movement” is understood to mean that the measuring device is continuously moved, manually or mechanically, wherein the measuring head of the measuring device is placed directly on the contacting layer. A combined measurement is taken, as an individual measurement in the series of measurements, at short time intervals during the movement.

A “movement” is also understood to mean that the following steps are repeatedly performed: positioning the measuring device at a prospective measurement location; fixing the measuring head on the covering layer or at a definable height above the covering layer; and taking the combined measurement as an individual measurement in the series of measurements.

Another aspect of the invention relates to a measuring device for measuring a layer thickness of a covering layer on a substrate. The measuring device can comprise a device for establishing a static magnetic field, which can be a permanent magnet or a static electromagnet, for example a coil fed with a direct current.

The measuring device can also comprise a device for establishing a dynamic magnetic field, which can be a dynamic electromagnet, for example a coil fed with an alternating current.

The measuring device can comprise at least one magnetic field sensor for measuring a static and a dynamic magnetic field, which can be a Hall sensor which can detect both a static and a dynamic magnetic field. Devices can also be used in which both establishing and detecting the dynamic magnetic field is implemented by means of a single element, for example a coil which is operated using an alternating current and exhibits a complex impedance which changes in accordance with the properties of the measured object, i.e. the substrate which is covered with a layer.

The measuring device can also comprise an evaluating unit using which the ascertained measurement values from measuring the static and the dynamic magnetic field can be compared with each other. A change in a substrate is identified in accordance with whether a reference relationship, which is established in a reference region, between measurement values which were ascertained using a static and a dynamic magnetic field measuring method remains unchanged in a test region. If the relationship between the measurement values obtained using different methods deviates from the reference relationship in the test region, then the substrate has been changed in the test region. A deviation of the measurement values from the reference relationship can be interpreted as a detection criterion for establishing a change in the substrate relative to the original state. If there is a deviation, the evaluating unit can output an acoustic or optical warning signal for an operator. The evaluating unit can also indicate the deviation graphically, for example in a 2D chart, and leave it to the operator to assess whether there is a change in the substrate.

In accordance with one embodiment, the measuring device can be designed to measure a static and a dynamic magnetic field simultaneously or near-simultaneously or sequentially. By measuring simultaneously or near-simultaneously, it is possible to take the measurements in the course of a movement by the measuring device within the locational range which is to be measured, such that the measurement location is the same for both measuring methods.

In accordance with another embodiment, the evaluating unit can be designed to process the measurement values before they are compared with each other, in order to enable the measurement values to be comparable. The processing involves using mathematical operations, the parameters of which have been ascertained from a calibration and/or zero adjustment, which have been performed prior to the combined measurement, in order for example to define a reference relationship and, on the basis of this, a detection curve. Comparing the measurement values can involve testing a relationship between the processed measurement values as to whether the relationship matches the reference relationship or whether the measurement values deviate from the detection curve.

The present invention shall be explained in more detail on the basis of example embodiments. There is shown:

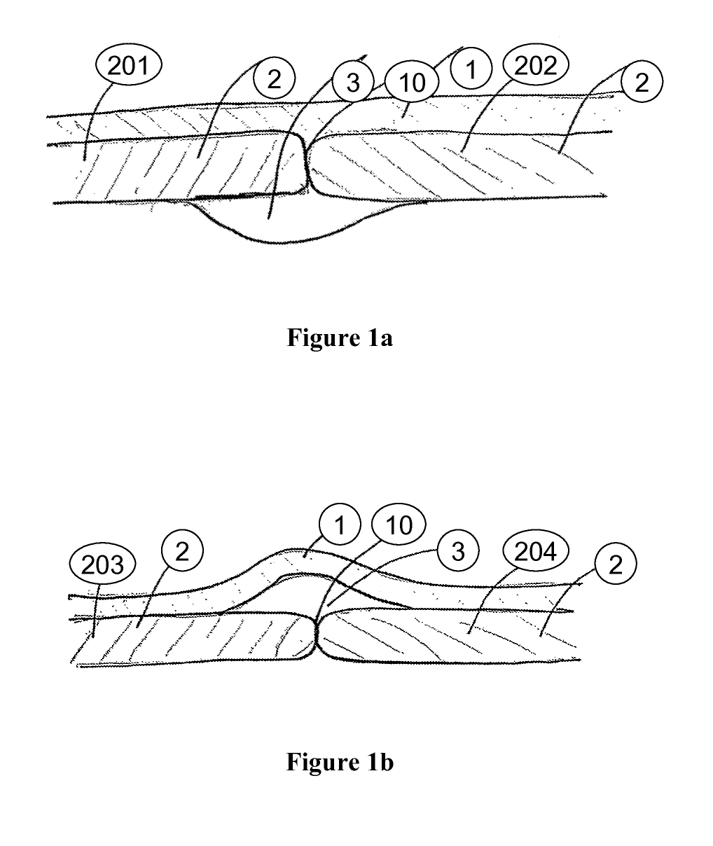

FIG. 1a a first example of a detectable change in a substrate;

FIG. 1b a second example of a detectable change in a substrate;

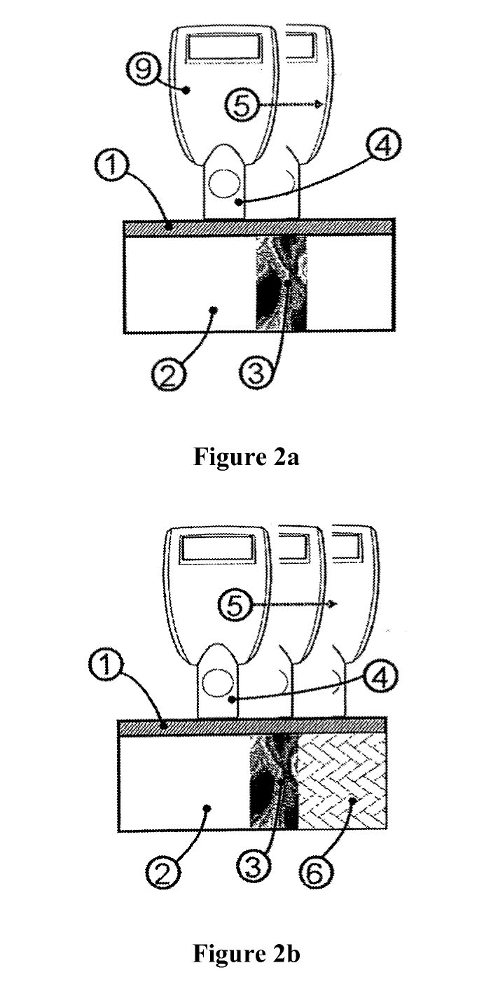

FIG. 2a localising a welding spot or welding seam or a structural change, wherein an electrically insulating and/or poorly conductive and poorly magnetisable coating 1 and an electrically conductive and magnetisable and/or ferromagnetic substrate 2 are shown, wherein the substrate comprises a welding seam 3 which exhibits different electrical and/or magnetic properties. The plugged-in measuring probe 4 in the central control unit 9 is guided 5 over the surface in order to localise the welding seam;

FIG. 2b localising a welding spot and/or welding seam and/or another material 6 which exhibits different electrical and/or magnetic properties to the original substrate and which is welded to the substrate via the weld;

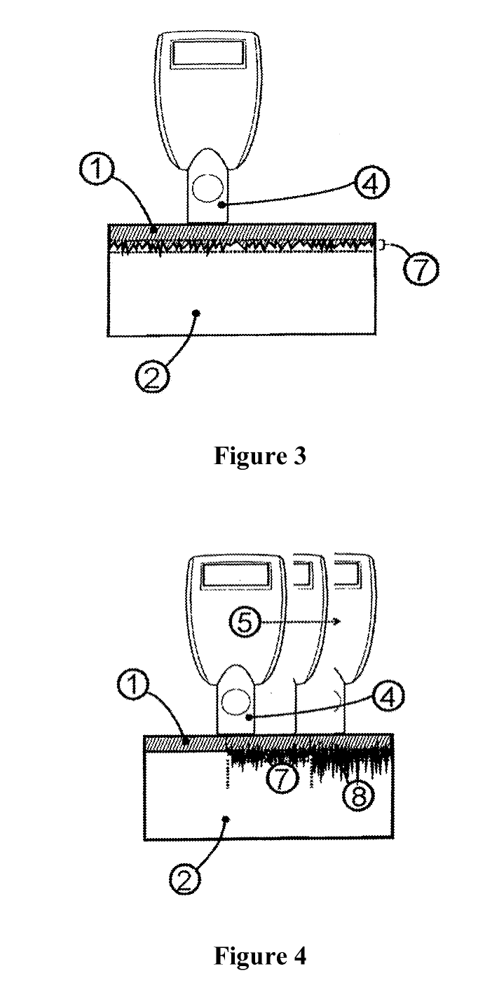

FIG. 3 qualitatively or quantitatively determining the roughness 7 of the substrate on a planar surface;

FIG. 4 localising changed substrate roughnesses 8 on a planar surface;

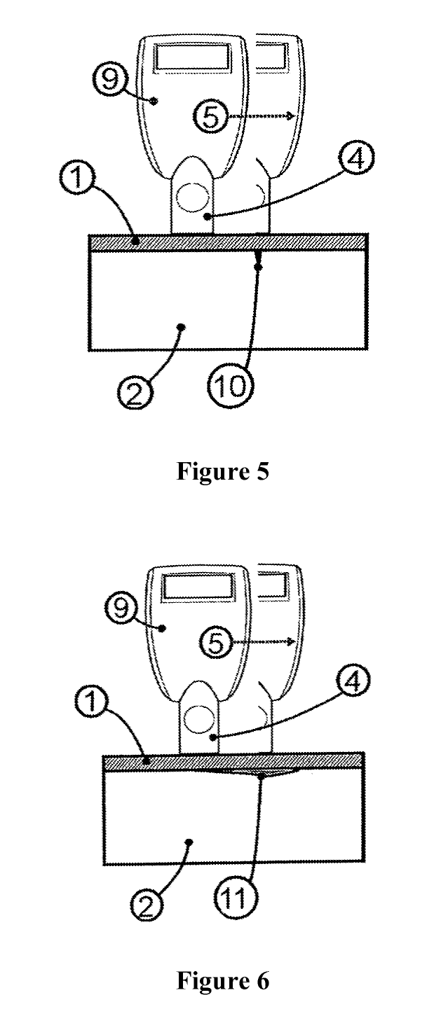

FIG. 5 localising cracks and holes in the substrate, wherein an example of a crack 10 is shown;

FIG. 6 localising stoppings, fillings or corrosion in the substrate which exhibit different electrical or magnetic properties. An example of a stopping 11 is shown;

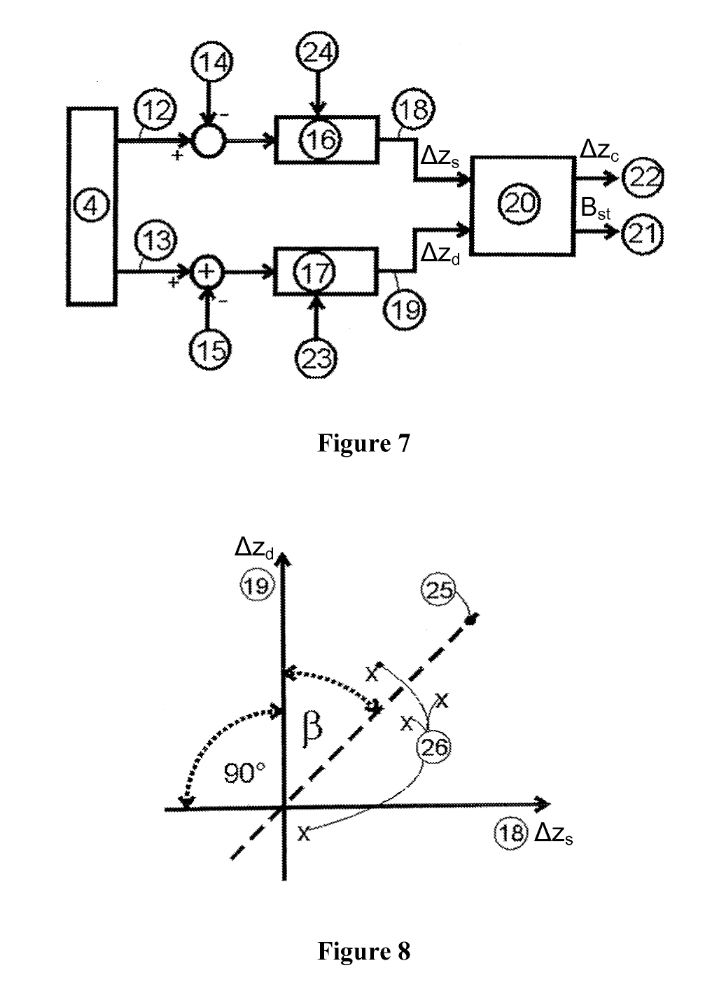

FIG. 7 a schematic representation of the measuring method using the two linearised measurement signals Δzₛ and Δz_{d} and the evaluating algorithm, such that the two items of measurement information, namely the substrate property Bₛₜ and the layer thickness Δz_{c}, can be evaluated separately and/or in an orthogonalised way. The measurement signal for determining the static and/or near-static magnetic field coupling into the substrate 12, and the eddy current measurement signal 13 for determining the dynamic magnetic field coupling are generally temperature-compensated;

FIG. 8 an example representation of the functionality of the algorithm, using a straight calibrating line as an example of a “location curve” and/or reference relationship in the Δzₛ/Δz_{d} plane which describes the change in the measurement values on the basis of the coating thickness, and the example pairs of values Δzₛ, Δz_{d} which exhibit a deviation with respect to the straight calibrating line on the basis of structural changes;

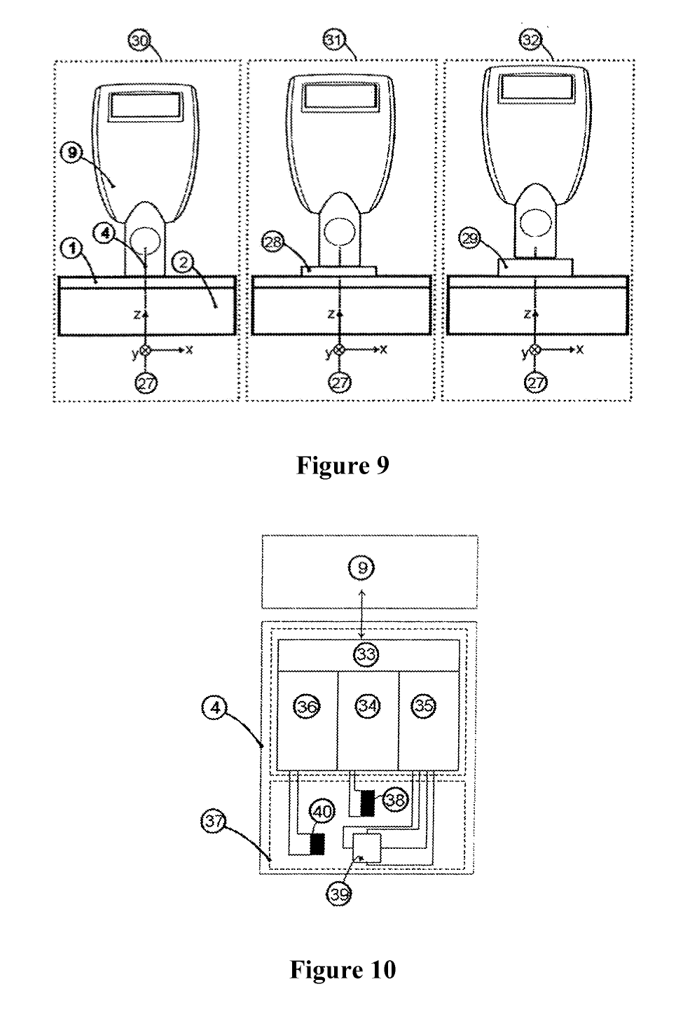

FIG. 9 an example representation of the combined zero adjustment and a one-point calibration using a reference coating and/or reference film or a two-point calibration using two reference films, wherein the thickness of the coating can also assume the extreme value zero, such that the measurement is taken practically directly on the uncoated substrate. For applications in which the coating thickness varies over a larger measuring range, it can be expedient for more than two calibrating films to be used in order to determine the calibrating functions;

FIG. 10 a schematic representation of the functional components of a measuring apparatus;

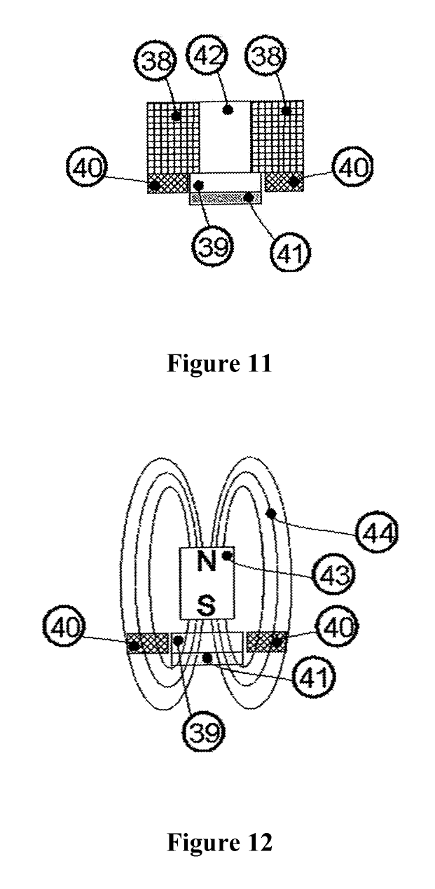

FIG. 11 an example representation of the mechanical design of a measuring head in section, comprising a coil for generating the static and/or near-static magnetic field and an eddy current coil for measuring eddy currents;

FIG. 12 an alternative mechanical design of a measuring head, comprising a permanent magnet for generating the static and/or near-static magnetic field and an eddy current coil for measuring eddy currents.

FIG. 1a shows a first example of a detectable change in a substrate, wherein a substrate 2 exists beneath a layer 1 covering the substrate 2. The substrate 2 comprises a first partial substrate 201, the material properties of which match those of a reference substrate, wherein a second partial substrate 202 has been affixed to the first partial substrate 201 by means of welding. It is not known whether the material properties of the second partial substrate 202 match those of the first partial substrate 201. The measurement is taken by a measuring device, wherein a welding seam 3 is formed on a side of the substrate 2 facing away from the measuring device.

At a first testing location, which is a location on the partial substrate 201 on or at a distance from the covering layer 1, a first combined measurement is taken using a combined static and dynamic magnetic measuring method. At a second testing location at a location on the partial substrate 202, a second combined measurement is taken under the same conditions as the first measurement. At a third testing location at a join 10 between the partial substrates 201, 202, a third combined measurement is taken under the same conditions as the first measurement.

A reference relationship between measurement values obtained using different measuring methods has been established beforehand on the basis of reference measurements in a reference region comprising a planar substrate surface. The reference relationship is a 1:1 relationship.

The first measurement establishes that the measurement values obtained at the first testing location using different measuring methods are identical to each other and/or bear a relation to each other or correspond to a 1:1 relationship. Accordingly, the detection criterion is not fulfilled and the first partial substrate 201 is identified as being unchanged relative to the reference substrate in the reference region.

If the second partial substrate 202 exhibits different material properties to the first partial substrate 201, for example a different magnetic permeability, the second measurement establishes that the measurement values obtained at the second testing location using different measuring methods deviate from each other. Accordingly, the detection criterion is fulfilled and the method in accordance with the invention identifies a change in the second partial substrate 202 relative to the reference substrate. The reasons for this are that on the one hand, there is a transition between two partial substrates 201, 202 which exhibit different material properties, for example magnetic permeability; and on the other hand, the join 10 exhibits changed structural properties, namely an indentation or recess. By contrast, the first and second partial substrate 201, 202 and the reference region exhibit a planar substrate surface.

The third measurement establishes that the measurement values obtained at the third testing location using different measuring methods deviate from each other, such that the detection criterion is also fulfilled at the third testing location.

If the second partial substrate 202 exhibits the same material properties as the first partial substrate 201, the detection criterion is not fulfilled after the second measurement. However, the detection criterion is fulfilled after the third combined measurement. The reason for this is the aforementioned change in the structural properties of the substrate 2 at the join 10 between the first and second partial substrate 201, 202.

FIG. 1b shows a second example of a detectable change in a substrate, wherein a substrate 2 exists beneath a layer 1 covering the substrate 2. The substrate 2 comprises a third partial substrate 203, the material properties of which match those of a reference substrate, wherein a fourth partial substrate 204 has been affixed to the third partial substrate 203 by means of welding. Unlike FIG. 1a, in which the welding location 3 is formed on the rear side of the substrate, the welding location 3 in FIG. 1b is formed on the front side of the substrate.

As in the example in accordance with FIG. 1a, three measurements are taken on the configuration in accordance with FIG. 1b, at three analogously positioned testing locations. The results of the first and second measurement do not exhibit any differences relative to FIG. 1a. In the third measurement over the join 10, the welding seam 3 is detected by the magnetic field of the measuring device in FIG. 1b, instead of the indentation 10 in accordance with FIG. 1a. The welding seam 3 exhibits a structural change relative to the partial substrates 203, 204. While this change does differ from the indentation 10 in FIG. 1a, the effect on the measurement results is not serious: the detection criterion is likewise fulfilled at the third testing location in accordance with FIG. 1b. There is merely a quantitative difference in the measurement results relative to FIG. 1a, because the welding seam 3—in addition to the structural change—also exhibits a change in the material properties relative to the partial substrates 203, 204. It is thus to be expected that the deviations between the measurement values and the detection curve—which is a 45° straight line in a 2D chart—are greater in the configuration in accordance with FIG. 1b than in the configuration in accordance with FIG. 1a.

FIG. 2a shows the basic design when inspecting motor vehicles. Damage to the steel body or a change in the steel body is sought, in order to detect repaired damage due to an accident, repaired hail damage or other fraudulent manipulations on the vehicle. Due to the variety of possible changes in the coat of paint and in the substrate, it is desirable to measure the coating thickness and/or changes in it and the properties of the substrate and/or changes in them.

In many applications, it is necessary to characterise and/or test the properties and/or change and/or ageing or the manipulation on highly magnetisable substrates and/or materials and/or surfaces, wherein the substrate can be coated with an electrically insulating and/or poorly electrically conductive and poorly magnetisable material of an unknown layer thickness.

The changed properties of the substrate can be localised by moving a measuring head and/or measuring probe over the surface and/or by moving the substrate to be examined, wherein translational, scanning or rotational movements are for example possible.

The measuring head can in particular also be positioned at a distance, wherein the contact between the head of the measuring probe and the surface is for example detected by the measurement signals and/or by means of a spring mechanism, such that measurement values are for example only detected or evaluated when the measuring probe is placed on the surface.

The measuring probe and/or test object can in this case be moved manually and/or automatically by a mechanical device.

One example of an application is that of testing vehicles, wherein welding seams or welding spots and/or exchanged steel parts beneath coats of paint are for example sought, in order to test the vehicle and/or vehicle part for manipulation and/or originality (see for example FIGS. 2a and 2b). Comparable applications are also to be found in the bridge, ship and boiler construction industries and in other steel constructions.

The size of the measuring probe and/or measuring head can deviate from the figures when adapted to the respectively obtaining application.

Another practical example application is that of characterising the surface roughness of a highly magnetisable and/or ferromagnetic substrate (see for example FIG. 3) or a change in said roughness (see for example FIG. 4), wherein the substrate can be coated with an electrically insulating and/or poorly electrically conductive material of an unknown layer thickness.

Another practical example application is that of localising cracks and/or hairline cracks or holes in a highly electrically conductive and magnetisable and/or ferromagnetic substrate or only in the surface of the same substrate, wherein the substrate can be coated with an electrically insulating and/or poorly electrically conductive and poorly magnetisable material of an unknown layer thickness.

In addition to the aforementioned applications, the invention can be used to non-destructively test the originality of chassis numbers or production numbers of motor vehicles, wherein the digits of the number and therefore the substrate have for example been manipulated and/or changed as a result of fraudulent intentions. Here, too, the highly electrically conductive and magnetisable and/or ferromagnetic substrate can be coated with a poorly electrically conductive and poorly magnetisable material of an unknown layer thickness.

The invention can also be used to inspect materials, in order for example to detect material ageing, material creep or material fatigue in the highly electrically conductive and magnetisable and/or ferromagnetic substrate which can also be coated with a poorly electrically conductive and poorly magnetisable material of an unknown layer thickness.

The object of the invention is solved by measuring the coupling of a static and/or near-static magnetic field into a magnetisable and/or ferromagnetic material and the coupling of at least one dynamic and/or alternating magnetic field, in parallel or sequentially over time, while taking into account the eddy currents into the simultaneously electrically conductive substrate.

The measuring procedure for determining the coupling of the static and/or near-static magnetic field is based on measuring the magnetic flux density using a magnetic field sensor which can detect static, near-static and/or dynamic magnetic fields. Hall sensors, GMR sensors, AMR sensors and coils comprising special magnetisable cores can preferably be used for this purpose. The static and/or near-static magnetic field can be generated using at least one separate coil or a permanent magnet.

The measuring procedure for determining the coupling of the dynamic magnetic field is based on a type of eddy current measuring procedure which uses the electromagnetic interaction between the coil and the substrate, while taking into account the induced substrate eddy currents and the dynamic substrate permeability. Within this context, the dynamic magnetic feedbacks which take into account the dynamic permeability and the eddy currents in the substrate can for example be detected using an exploring coil measuring procedure based on a separate coil (mono-coil method) or using a transformer-type exploring coil measuring procedure comprising at least two separate coils.

Such a solution has the advantage that no eddy currents and/or insignificant eddy currents are generated in the substrate by the static and/or near-static measurement, as compared to the dynamic magnetic field coupling, such that particularly significant structural changes, defects or changes in the substrate can be detected by comparing the two measuring procedures.

Another advantage is that in addition to the analysis of the structural measurement by means of measuring the static magnetic field, the layer thickness and/or the distance from the highly magnetisable substrate can also be particularly clearly determined, since the dynamic magnetising properties of the substrate does not have any substantial effect on the static measurement.

A common scaling or separate scalings, calibrations and as applicable at least one conversion of the two measurement signals are also provided in accordance with the invention and enable the changes in measurement signals due to a local change in the substrate properties to be differentiated from the changes in measurement signals due to a change in the layer thickness.

The measuring principle is based on comparing the different material properties when magnetised using a static and/or near-static magnetic field and when magnetised with an eddy current feedback due to the dynamic and/or alternating magnetic field.

A “substrate” and/or “reference substrate” is understood to mean any highly electrically conductive substrate or substrate structure which exhibits good magnetisable and/or ferromagnetic properties.

A “coating” and/or “coating only” and/or “reference coating” is understood to mean any coating which is electrically insulated and/or exhibits poorly electrically conductive and not substantially magnetisable properties.

The change in the layer thickness of a coating on the substrate results in a particular change in the two measurement signals. In order to functionally determine the changes in the two measurement signals due to the change in the coating thickness, a combined and/or complementary zero adjustment, scaling and/or calibration of the two measuring procedures, respectively, on a reference position of the reference substrate is provided for the measuring method.

The combined zero adjustment of the two measuring procedures can be made on the reference substrate, with or without a coating, wherein a synchronous detection of the measurement values of the two measuring procedures or a near-synchronous detection with automatic alternation between measuring modes can be provided.

The calibrating and/or scaling functions of the two measuring procedures can be determined by measurements on different reference coatings, such that the changes in the measurement signals due to a change in the coating thickness are determined for both measuring procedures.

Defined films which are placed and/or positioned on the reference position can for example serve as reference coatings. This has the advantage that the same substrate respectively obtains when the different reference coatings are measured on the reference point and/or reference position (27), such that no substantial errors can arise in this way when determining the sampling points for calculating the two calibrating functions.

Another procedure for simultaneously or near-simultaneously ascertaining the two calibrating functions by means of reference coatings is to provide reference substrates which are coated in a defined way.

Another procedure for determining the calibrating functions, without using special reference coatings, can be to position the measuring probe at a determined and/or defined distance from the surface, wherein for example an external device and/or a mechanical device implemented as a measuring probe can position the measuring probe at a defined height above the substrate and/or reference point—as applicable, together with the coating. An external device can for example be a robot arm or a lifting device in a rolling or coating facility, which features a path measuring device or position measuring device. A device implemented as a measuring probe can for example be realised using piezo-based or electromagnetic actuators which position the tip of the measuring probe and/or the measuring head at a defined height.

The calibrating functions can be determined, on the basis of the reference sampling points determined when measuring the reference coatings, by means of interpolation or approximation methods, wherein for example linear, cubic or other, higher-order polynomials can preferably be locally or globally used over the range of values.

Making a zero adjustment on a reference position and determining, in combination, the complementary calibrating functions for the two measuring procedures with the aid of at least one reference coating enables structural analysis measurements on many different coated and uncoated reference substrates, even when there is a change in the coating thickness.

The combined zero adjustment and the combined calibrations using at least one or more reference coatings enable magnetically static measurement signals and the magnetically dynamic measurement signal on the original and/or identical reference substrate to be linearised, such that the linearised measurement signal Δzₛ is calculated for the static measuring procedure and the linearised measurement signal Δz_{d} is calculated for the dynamic measuring procedure. The coating thickness and/or changes in it can thus be redundantly and thus precisely detected using the two measuring procedures, if the reference substrate does not show any substantial physical changes.

The zero adjustment and the combined calibration have the purpose of detecting the different substrate properties of different reference materials. In addition to physical properties such as for example electrical conductivity and magnetic permeability, the geometry and/or topography are also to be taken into account within this context. In practical applications, special calibrations are often for example determined on concave or convex measurement areas. It is therefore advantageous to also make combined zero point adjustments and perform calibrations in the direct application, in addition to the stored zero point adjustment values and/or calibrations in the measuring apparatus and/or measuring probe.

Linearising the two measurement signals by means of calibrating the two measurement signals in combination thus preferably produces a linear straight calibration line as a “location curve” and/or reference relationship in the Δzₛ/Δz_{d} plane. It would also be possible to analyse the substrate structure using non-linearised measurement signals. This would however have the disadvantage that instead of a straight calibration line in the Δzₛ/Δz_{d} plane, a different location curve profile would exist with changes in the coating thickness, and the deviations from this complicated location curve due to structural changes in the substrate would be more difficult to evaluate.

The pair of values Δzₛ, Δz_{d} can be graphically displayed by a numerical display or by graphically displaying the pair of values in the Δzₛ/Δz_{d} plane.

A deviation between the two linearised measurement signals Δzₛ and Δz_{d} and the straight calibration line as a location curve in the Δzₛ/Δz_{d} plane indicates a change in the substrate properties which is signalled to the user by an optical or acoustic alarm and/or indication and/or is evaluated by an automatic evaluating device, for example in a facility. Preferably, loudspeakers and/or piezo signal emitters can for example be used for the acoustic alarm signal. Lamps, LEDs, liquid crystal displays and/or computer screens can for example preferably be used for the optical signal.

In addition to the alarm for indicating a structural abnormality and/or a change in the same and the accompanying deviation from the straight line in the Δzₛ/Δz_{d} plane, another alarm can also be signalled when only one or both measurement signals Δzₛ, Δz_{d} or a change in them exceeds or falls below a defined range of values. This alarm can be signalled and/or automatically evaluated in the same way or in a different way.

It is also provided that the degree of deviation between the two linearised measurement signals Δzₛ and Δz_{d} and straight calibration line or a change in it is signalled to the user, wherein graphic or acoustic signalling in the form of an analogue or near-analogue signal is preferably used, wherein the degree of deviation Bₛₜ from the straight calibration line can also for example be weighted and/or scaled in accordance with the signal Δzₛ and/or the signal Δz_{d} and/or at least one other settable parameter. A bar display, a needle deflection and/or the brightness and/or colour can serve as a graphic representation, such that the degree of deviation is displayed in an analogous or near-analogous way.

For documenting or evaluating the data, it is possible to provide for the measurement signals Δzₛ, Δz_{d} and the degree of deviation from the original reference substrate to be stored, such that the measurement data can for example be transferred to a personal computer to be evaluated and documented.

In another preferred embodiment, it is possible to provide for not only one but rather a number of spatially offset measuring probes to be provided, such that a number of measurements can be taken simultaneously or near-simultaneously, wherein it is particularly advantageous if a detector is provided for measuring the structure in each spatial and/or surface direction. Since the change in the substrate structure is thus separately detected in all the spatial and/or tangential surface directions, the result is that changes in a substrate are localised or identified particularly simply and quickly.

In another preferred embodiment, it is also possible using the invention to provide for the structure to be measured and/or analysed even when not in contact with the substrate and/or coating. In this case, the distance and/or height from the substrate surface is measured instead of the coating thicknesses. This non-contact mode has the advantage that the measuring probe has no contact with the coating or substrate, such that no friction is generated. Such an embodiment of the invention can for example be used when inspecting steel railway lines or steel rolling mills or when inspecting steel welding spots, wherein the steel substrate can for example be analysed independently of a coating.

For measuring the layer thickness on the ferromagnetic substrate, many different measuring procedures are used in existing manual inspections using mobile layer thickness measuring apparatus, wherein a distinction is drawn in principle between the magnetic field change measuring procedure and the magnetic inductive measuring procedure. In specific apparatus embodiments for measuring coating thicknesses on non-ferromagnetic substrates, layer thickness measuring apparatus also comprise an eddy current measuring procedure in combination. In addition to manually switching between the magnetic field change measuring procedure and the eddy current measuring procedure, it is also possible in such measuring apparatus to provide an automatic system which automatically activates the eddy current measuring procedure for measuring the coating thickness on an electrically conductive and non-ferromagnetic substrate when the substrate is not a ferromagnetic substrate and/or when measuring the coating thickness using the magnetic field change measuring method determines a coating thickness which is too large.

Unlike the invention described here, however, these layer thickness measuring apparatus do not evaluate the measurement signals of the eddy current measuring procedure and the magnetic field change procedure on the ferromagnetic and electrically conductive substrate in combination, such that in addition to measuring the layer thickness, the structural properties of the ferromagnetic substrate are analysed and indicated continuously and/or in an analogue way. A synchronous zero adjustment and a synchronous calibration of the two measuring procedures on an uncoated or coated substrate is also not possible. A non-contact mode of the measuring probe for structural analysis, and determining a distance with regard to the ferromagnetic substrate, are also not provided.

For measuring the substrate structure and the layer thickness, structure-measuring apparatus based on eddy currents are used in existing manual inspections, wherein measuring methods of evaluating amplitude/phase and measuring methods of evaluating frequency/attenuation following impulse or jump excitation are for example used.

Unlike the invention described here, however, these structure-measuring apparatus based on eddy currents cannot detect static magnetic fields, such that the purely static and/or near-static magnetic properties of the substrate cannot be detected or not sufficiently precisely. In particular, it is only by detecting the static and/or near-static magnetic properties of the substrate by means of magnetic field sensors, such as for example a Hall sensor, that it is then possible to compare the static properties with the dynamic magnetic properties of the magnetisable substrate and detect significant changes in the substrate structure. The non-linear and/or hysteretic properties and the simultaneous and in most cases different dynamic properties of the ferromagnetic materials result in substantial differences between static (and/or near-static) and dynamic magnetic excitation, which are used by the invention described here.

In accordance with the invention, a measuring probe is used which simultaneously or sequentially uses the static properties by means of a magnetic field change measuring procedure and the dynamic electromagnetic properties by means of an eddy current measuring procedure.

FIG. 7 shows the two measurement signals from the measuring probe 4 being processed, wherein the measuring probe 4 outputs the temperature-compensated magnetic field measurement signal 12 and the temperature-compensated eddy current measurement signal 13. The magnetic field reference value 14 is subtracted from the magnetic field measurement signal 12, and this difference is the argument for the magnetic field calibrating function 16, the result of which is the calibrated magnetic field signal Δzₛ 18. Analogously, the eddy current reference value 15 is subtracted from the eddy current measurement signal 13, and this difference is the argument for the eddy current calibrating function 17, the result of which is the calibrated eddy current signal Δz_{d} 19.

The processing of the signals in accordance with FIG. 7 can also be performed in the measuring probe.

The combined zero adjustment 30 of the two measuring procedures simultaneously (and/or near-simultaneously) determines the magnetic field reference value 14 and the eddy current reference value 15 on an x,y reference position 27, such that the difference [12−14] and the difference [13−15] respectively assume the value zero.

The combined calibrations by means of different reference coatings 28, 29 and/or distances simultaneously (and/or near-simultaneously) determine the magnetic field calibrating parameter 24 and the eddy current calibrating parameter 23 on the x,y reference position 27 for the two measuring procedures. The calibrating parameters 23 and 24 are preferably selected and/or calculated in such a way that the calibrated magnetic field signal Δzₛ 18 and the calibrated eddy current signal Δz_{d} 19 produce a straight distance/location curve profile 25 in accordance with the coating thickness and/or distance, exhibiting an angle of for example β=45°.

FIG. 8 shows the straight distance/location curve profile 25 exhibiting the angle and an example of deviating pairs of measurement values Δzₛ, Δz_{d} 26 which deviate from the straight distance/location curve profile 25 due to a structural change in the substrate.

The magnetic field calibrating function ƒ_{MK}(z) 16 can for example be determined by a polynomial description:

ƒ_{MK}(z)=Σᵢ₌₁^{N}aᵢzⁱ (1)

such that the values between the sampling points ascertained using the calibrating films are approximated or interpolated as well as possible for the measurement signal Δzₛ, wherein the value N can correspond to the number of calibrating films, and the magnetic field calibrating parameters aᵢ 24 used as an example for this case are determined by interpolation algorithms or approximation algorithms. This example of the magnetic field calibrating function is not limited, since the calibrating function can also be defined by other global and related local functions. Another solution for defining the magnetic field calibrating function is for example to use a so-called akima spline interpolation algorithm.

The eddy current calibrating function ƒ_{WK}(z) 17 for calculating the measurement signal Δz_{d} can be determined in an analogous way:

ƒ_{WK}(z)=Σᵢ₌₁^{N}bᵢzⁱ (2)

such that the values between the sampling points ascertained using the calibrating films are approximated or interpolated as well as possible for the measurement signal Δz_{d} using the eddy current calibrating parameters bᵢ 23. This example of the eddy current calibrating function is also not limited and independent, since the calibrating function can also be defined by other global and related local functions. Another solution for defining the eddy current calibrating function is for example to use a so-called akima spline interpolation algorithm.

The structural properties of the ferromagnetic material are evaluated by the structure-evaluating algorithm 20, the arguments of which are the calibrated magnetic field signal Δzₛ 18 and the calibrated eddy current signal Δz_{d} 19. The results of the structure-evaluating algorithm 20 are the structure assessment value Bₛₜ 21 and the distance assessment value Δzₛ 22. The structure assessment value Bₛₜ 21 can for example simply be calculated by the difference between the calibrated magnetic field signal Δzₛ 18 and the calibrated eddy current signal Δz_{d} 19:

Bₛₜ=Δz_{d}−Δzₛ (3)

if the preferred straight distance/location curve profile 25 is through the zero point (0, 0) and the angle β in FIG. 8 is equal to 45°. This example is however not limited, since the assessment of the straight distance/location curve profile 25 or of any other distance/location curve profile can be calculated by another functional and/or vectorially functional relation. Within this context, it is also for example possible to perform a standardisation and/or weighting in accordance with at least one parameter and/or the input values Δzₛ and/or Δz_{d}. This has the advantage that the sensitivity of the indicated and/or evaluated structure assessment value Bₛₜ is particularly sensitive or insensitive in parts of defined regions of the Δzₛ/Δz_{d} plane, which can be different depending on the application and can therefore be desired to be settable by the user or by an automatic system.

The distance assessment value Δz_{c} 22 represents the distance between the pair of values Δzₛ, Δz_{d} and the Δzₛ axis or Δz_{d} axis, depending on the application:

Δz_{c}=min(ΔzₛvΔz_{d}) (4)

whereby the user or a subsequent evaluation obtains additional information about the deviation of the coating as compared to the coating on the x,y reference position 27. This example is however not limited, since the change in the pair of values Δzₛ, Δz_{d} as compared to the pair of values on the reference position can also be calculated and/or evaluated by another functional relation. The distance assessment value Δz_{c} 22 can for example also comprise the distance between the pair of values Δzₛ, Δz_{d} and the origin (0, 0) or the angular distance from an axis.

FIG. 9 shows the combined zero adjustment 30, the first calibration measurement 31 using the first reference layer thickness 28 and the second calibration measurement 32 using the second reference layer thickness 29. The zero adjustment 30 and the calibrating measurements 31, 32 are each taken on the x,y reference position 27. In this example, the measuring probe 4 is plugged into the central control unit 9; the measurement data can however also be transferred via a cable and/or a line or via a radio connection. The magnetic field reference value 14 and the eddy current reference value 15 are determined in the combined zero adjustment 30. After the first calibration measurement 31 and after the second calibration measurement 32, the magnetic field calibrating parameters 24 and the eddy current calibrating parameters 23 are determined by means of approximation algorithms or interpolation algorithms.

FIG. 10 shows an example of the functional design of a hand-held measuring apparatus comprising the central control unit 9 which enables the user to comfortably operate the apparatus using keys and menu navigation and which indicates the measurement values by means of a liquid crystal display. Within this context, the values Δzₛ, Δz_{d} can be indicated as layer thickness information, and the structure assessment value Bₛₜ 21 and/or the distance assessment value Δz_{c} 22 can be indicated in separate numerical displays or a separate bar display.

The measuring probe comprises a combined measuring head 37 and measuring probe control electronics 33 which on the one hand ensure that the measurement signals 12, 13 are communicated and/or transferred from the measuring probe to the central control unit 9 in an analogue or digital form and on the other hand control the internal detection of the temperature-compensated magnetic field measurement signal 12 and the temperature-compensated eddy current measurement signal 13. The measuring probe control electronics 33 co-ordinate the magnetic field control electronics 34, the magnetic field sensor evaluating electronics 35 and the eddy current evaluating electronics 36.

FIG. 11 shows the geometric arrangement of the magnetic field coil 38, the eddy current coil 40 and the magnetic field sensor 39 of the measuring head 37, in section. A measuring head protector 41 is also provided which protects the measuring head 37 and/or the magnetic field sensor 39 against mechanical and/or electrical influences. By using a highly magnetisable core 42, the coupling to the magnetisable substrate can be measured particularly clearly. Within this context, an external magnetic shielding which exhibits high permeability and is open towards the substrate could also be provided in another design variant.

In order to measure the magnetic field measurement signal 12, a static and/or near-static current from the magnetic field control electronics 34 flows through the magnetic field coil 38. The static or near-static magnetic field thus generated couples depending on the permeability of the substrate and the distance and/or thickness of the coating which is not substantially magnetisable. The magnetic flux density in the magnetic field sensor 39 changes in accordance with the coupling of the magnetic field of the magnetic field coil 38, such that said magnetic field is detected by the magnetic field sensor evaluating electronics 35. The magnetic field measurement signal 12 is determined from this measuring procedure using a microprocessor and is stored in the measuring probe control electronics 33.

Aside from a purely static magnetic field through the magnetic field coil 38, the current throughflow intensity through the magnetic field coil 38 can also be changed in increments and/or reversed in terms of polarity, such that it is possible to take measurements for the different near-static magnetic field intensities and/or magnetic field orientations. Among other things, this has the advantage that error influences due to an external disruptive static magnetic field can be computationally eliminated.

A Hall sensor which can detect both static and near-static magnetic fields is preferably used for the magnetic field sensor 39, wherein the electrical wiring of the Hall sensor for evaluating the static and near-static magnetic field which penetrates the Hall sensor can be based on a direct current evaluating technique or an alternating current evaluating technique. In the case of an alternating current evaluating technique, a so-called lock-in evaluating technique is for example used. In addition to a Hall sensor, however, other magnetic field sensors can also in principle be used, such as for example giant magnetoresistance (GMR) sensors, anisotropic magnetoresistance (AMR) sensors, tunnel magnetoresistance (TMR) sensors or superconducting quantum interference devices (SQUIDs). In addition, a coil comprising at least one special magnetic core material, preferably exhibiting non-linear magnetic properties, can also be used for measuring the static and/or near-static magnetic field.

In another measuring head design variant, which is for example shown in FIG. 12, the static magnetic field 44 can be provided and/or generated by a permanent magnet 43. However, this simpler variant has the disadvantage that disruptive static magnetic fields from the substrate exert a not insignifcant influence on the magnetic field measurement signal, such that structural changes in the substrate and spontaneous substrate magnetisations cannot be optimally separated from each other.

In order to measure the eddy current measurement signal 13, an alternating current for example flows through the eddy current coil 40. The alternating magnetic field thus generated couples into the substrate in accordance with the electrical and magnetic properties and the distance and/or thickness of the coating, which is not substantially magnetisable and not substantially electrically conductive, such that the impedance and/or impedance magnitude of the eddy current coil 40 is changed, taking into account the retroactive alternating currents in the substrate.

The change in the impedance magnitude of the eddy current coil 40 can be evaluated by the eddy current evaluating electronics in different ways and/or using different techniques and can therefore provide the eddy current measurement signal 13 in different ways. In this regard, a distinction is to be drawn between the frequency modulation technique, amplitude modulation technique, transient impulse response technique and transient step response technique.

In the frequency modulation technique, the eddy current coil 40 is a part of an excited oscillating circuit, the resonance and/or eigenfrequency of which is dependent on the complex impedance magnitude. Changing the impedance magnitude changes the eigenfrequency and therefore upsets the oscillating frequency of the oscillating circuit. In this case, the oscillating frequency of the oscillating circuit is the eddy current measurement signal 13.

A typical average oscillating frequency for the frequency modulation technique is about 12 MHz, such that only a low penetration depth of the eddy currents into the substrate exists due to this high frequency, and changes in the surface of the substrate can thus be detected particularly well.

In the amplitude modulation technique and/or lock-in technique, an electrical sinusoidal alternating current I_{WS}=I_{WS}e^{iΩt}=I_{WS}e^{jφ} at a constant frequency flows through the eddy current coil, in order to determine the complex impedance magnitude Z_{WS} of the eddy current coil 40 by measuring the complex voltage U_{WS}=U_{WS}e^{jΩt}=U_{WS} e^{jφ} applied to the eddy current coil:

$${\underline{Z}}_{WS} = \frac{{\underline{U}}_{WS}}{{\underline{I}}_{WS}} = \frac{{U}_{WS}}{{I}_{WS}} {e}^{jϕ} = {Z}_{WS } {e}^{jϕ} \qquad ( 5 )$$

wherein the magnitude of the impedance Z_{WS} and/or the phase φ can represent the eddy current measurement signal.

The excitation frequencies in the amplitude modulation technique can be selected such that different penetration depths of the eddy currents can be set. This has for example the advantage that changes in the substrate at different depths can be detected. In this regard, specific depths can also be detected by measuring at a number of frequencies.

The transient impulse and/or step response techniques are based on an oscillating circuit, wherein here, too, the eddy current coil represents a component of an oscillating circuit. Once the oscillating circuit has been excited using an impulse signal or step signal, the transient behaviour of the oscillating circuit is evaluated over time, such that the transient frequency and/or transient amplitude determines the eddy current measurement signal.

In a further variant, a third measurement signal or even higher-order measurement signals can be detected in addition to the existing temperature-compensated magnetic field measurement signal 12 and the temperature-compensated eddy current measurement signal 13, wherein all the signals are taken into account in parallel in an analoguous way, in accordance with FIG. 7, with a zero adjustment and calibration. An electrically capacitive measuring principle and/or sensor could for example preferably be used for this purpose. In this case, too, the parameters with regard to the zero adjustment and the calibration could be synchronously taken into account and/or calculated in an analoguous way as a function of the coating and/or the distance in a measuring procedure in accordance with FIG. 9. In this case, the structural properties would be evaluated not only in the Δzₛ/Δz_{d} plane but rather in a three-dimensional or higher-order signal space from the three and/or higher-order calibrated measurement signals. In this regard, the third and/or higher-order measurement signal can also represent the real and/or imaginary part of an electrically complex capacitive or inductive sensor, wherein temperature compensation can be provided for all the signals.

### REFERENCE SIGNS

1 coating: electrically insulating and/or poorly conductive and poorly magnetisable coating
2 substrate: electrically conductive and magnetisable and/or ferromagnetic substrate
3 welding seam, welding spot or structural change in the material
4 measuring probe
5 movement: manual or automated movement of the measuring apparatus and/or measuring probe over the surface
6 substrate exhibiting different electrical and/or magnetic properties to the substrate 2
7 qualitative or quantitative measure of the roughness of the substrate surface
8 substrate roughness exhibiting different geometric and/or electrical and/or magnetic physical properties to the roughness 7
9 central control unit for operating, evaluating, transferring and/or indicating the measurement results
10 cracks, holes or other partial abnormalities exhibiting different electrical and/or magnetic properties
11 stoppings, fillings or corrosion
12 temperature-compensated magnetic field measurement signal of the measuring procedure for determining the static and/or near-static magnetic field coupling into the substrate (for example, the magnetic field change measuring procedure)
13 temperature-compensated eddy current measurement signal of the eddy current measuring procedure
14 magnetic field reference value for the magnetic field measurement signal of the static and/or near-static magnetic field coupling which is for example used for a zero adjustment
15 eddy current reference value for the eddy current measurement signal of the eddy current measuring procedure which is for example used for a zero adjustment
16 magnetic field calibrating function for the measurement signal of the static and/or near-static magnetic field coupling
17 eddy current calibrating function for the measurement signal of the eddy current measuring procedure
18 calibrated magnetic field signal Δzₛ and/or the change corresponding to the static and/or near-static magnetic field coupling
19 calibrated eddy current signal Δz_{d} and/or the change corresponding to the eddy current measuring procedure
20 structure-evaluating algorithm, such that the two items of measurement information, namely the substrate property and the layer thickness, can be evaluated separately and/or in an orthogonalised way by the user
21 structure assessment value Bₛₜ which is a measure of and/or value for the structural properties of the substrate and/or changes in them
22 distance assessment value Δz_{c} which is a measure of and/or value for the thickness of the coating and/or changes in it
23 eddy current calibrating parameter for the scaling and calibrating function of the measurement signal of the eddy current measuring procedure
24 magnetic field calibrating parameter for the scaling and calibrating function of the measurement signal of the static and/or near-static magnetic field coupling
25 distance/location curve profile which describes the change in the two measurement signals Δzₛ and Δz_{d} in accordance with changes in not highly magnetisable and not highly conductive layer thicknesses on the substrate, wherein a straight line preferably characterises the profile by way of example
26 example combinations of measurement values and/or vectors comprising the tuples Δzₛ and Δz_{d} which do not lie on the location curve 25 due to a structural change with respect to a reference substrate
27 x,y reference position
28 first reference layer thickness and/or reference layer thickness 1, which is for example realised using a film
29 example reference coating and/or reference layer thickness, which is for example realised using a film
30 combined zero adjustment on the reference position
31 first calibration measurement on the reference position
32 second calibration measurement on the reference position
33 measuring probe control electronics
34 magnetic field control electronics
35 magnetic field sensor evaluating electronics
36 eddy current evaluating electronics
37 combined measuring head
38 magnetic field coil (static and/or near-static magnetic field)
39 magnetic field sensor for measuring the static and/or near-static magnetic field
40 eddy current coil for measuring eddy currents
41 measuring head protector for the measuring head
42 coil core exhibiting a high magnetic permeability
43 permanent magnet
44 magnetic field of the permanent magnet
201 first partial substrate
202 second partial substrate
203 third partial substrate
204 fourth partial substrate

1. A method for determining whether there is a change in a substrate beneath a layer covering the substrate, wherein:
a) at one location on the substrate, a combined magnetic and/or electrical measurement is taken on or at a distance from the covering layer using at least two different measuring methods; and
b) an examination is conducted as to whether a relationship between measurement values which are ascertained using different measuring methods matches a reference relationship, wherein if there is a deviation, it is established that the substrate has been changed.

2. The method according to claim 1, wherein following Step a) of taking a combined measurement, an examination is conducted as to whether the values obtained using the at least two different measuring methods are identical, wherein if the values are not identical, it is established that the substrate has been changed.

3. The method according to claim 1, wherein the obtained measurement values are assigned to a layer thickness of the covering layer.

4. The method according to claim 1, wherein the at least two different measuring methods are a static measuring method and a dynamic measuring method.

5. The method according to claim 1, wherein a calibration is respectively performed for each measuring method, before the combined measurement is taken.

6. The method according to claim 1, wherein a zero adjustment is respectively made for each measuring method, before the combined measurement is taken.

7. The method according to claim 5, wherein the calibration and/or zero adjustment involves at least one combined measurement which is taken at a location on the substrate at which one or more calibrating layers, which exhibit predetermined and preferably different thicknesses, are placed on the covering layer.

8. The method according to claim 1, wherein the combined measurement comprises at least two partial steps, wherein in one partial step, a measurement is taken using only one of the at least two measuring methods, and wherein the partial steps are performed simultaneously or near-simultaneously or sequentially.

9. The method according to claim 1, wherein a series of measurements comprising a multitude of combined measurements are taken at different locations on the substrate, wherein a locational dependency between the measurement values enables a statement about the location or locational range at which the substrate has been changed.

10. The method according to claim 8, wherein the series of measurements are taken by means of a measuring device, wherein the series of measurements are taken during a movement of the measuring device on or at a distance from the covering layer.

11. A measuring device for measuring an electrical and/or magnetic field on or at a distance from a covering layer on a substrate, comprising:
a device for establishing a static magnetic field;
a device for establishing a dynamic magnetic field;
at least one magnetic field sensor for measuring a static and a dynamic magnetic field; and
an evaluating unit using which measurement values obtained from measuring the static magnetic field and from measuring the dynamic magnetic field can be compared with each other.

12. The measuring device according to claim 11, wherein the measuring device is designed to measure a static and a dynamic magnetic field simultaneously or near-simultaneously or sequentially.

13. The measuring device according to claim 11, wherein the evaluating unit is designed to process the measurement values before they are compared with each other, in order to enable the measurement values to be comparable.

14. The measuring device according to claim 11, wherein the measurement values are assigned to a layer thickness of the covering layer.

15. The measuring device according to claim 11, wherein the measuring device is designed to take individual measurements and/or series of measurements, in particular for a calibration and/or zero adjustment, as measurements positioned at a defined distance, by positioning a measuring head of the measuring device at a defined distance, preferably by means of an external device and/or a mechanical device which is integrated in the measuring device.
